(19) United States
(12) Patent Application Publication
(10) Pub. No.: US 2026/0246182 A1
(43) Pub. Date: Aug. 20, 2026

(54) ELECTRONIC ASSEMBLY

(71) Applicant: Wistron Corporation, New Taipei City (TW)

(72) Inventors: Li Ren WANG, New Taipei City (TW); Sheng Chia HSU, New Taipei City (TW)

(21) Appl. No.: 19/175,270

(22) Filed: Apr. 10, 2025

(30) Foreign Application Priority Data
Feb. 14, 2025 (TW) 114105554

(51) Int. Cl. H01R 13/24; H01R 12/70; H01R 12/71; H05K 1/14

(52) U.S. Cl. CPC H01R 13/2421; H01R 12/7052; H01R 12/7076; H01R 12/716; H01R 13/2471; H01R 13/2485; H01R 13/2492; H05K 1/144; H05K 2201/2018

(57) ABSTRACT

An electronic assembly is disclosed. The electronic assembly includes a first substrate, a second substrate, and a connector device. The first substrate includes a first connecting portion, and the first connecting portion has a first connecting area. The second substrate includes a second connecting portion, and the second connecting portion has a second connecting area, wherein the second connecting area is larger than the first connecting area. The connector device is disposed between the first connecting portion and the second connecting portion.

### CROSS REFERENCE TO RELATED APPLICATION

This application claims the priority benefit of Taiwan Patent Application No. 114105554, filed on Feb. 14, 2025. The entirety of the mentioned above patent application is hereby incorporated by reference herein and made a part of this specification.

### BACKGROUND OF THE INVENTION

### 1. Field of the Invention

The present invention relates to an electronic assembly. Specifically, the present invention relates to an electronic assembly including a connector device to respectively connect two connecting portions having connecting points arranged in arrays with different pitches.

### 2. Description of the Prior Art

As process technology advances, the sizes of semiconductor components have become smaller, allowing for more components to fit on a single wafer, which can be exemplified by the development of System On Wafer (SOW). SOW integrates systems directly on the wafer, wherein signal and power transmission between the wafer and a circuit board is achieved through pins that contact the pads on the wafer and the pads on the circuit board. However, in such a contact process, it easily suffers from poor contact due to assembly tolerances. Therefore, addressing the contact issues caused by assembly tolerances presents a significant challenge for the industry.

### SUMMARY OF THE INVENTION

The present invention provides an electronic assembly, which includes a connector device to connect two connecting portions having connecting points arranged in arrays with different pitches, thereby dispensing with the need for positioning each layer separately during the assembly process and saving time.

The present invention provides an electronic assembly, which includes a connector device having a plurality of elastic connectors radially arranged to absorb larger assembly tolerances.

The present invention provides an electronic assembly, which includes a positioning component to position a plurality of elastic connectors, maintaining the inclined angle of each elastic connector.

In an embodiment of the present invention, the electronic assembly includes a first substrate, a second substrate, and a connector device. The first substrate includes a first connecting portion, and the first connecting portion has a first connecting area. The second substrate includes a second connecting portion, and the second connecting portion has a second connecting area, wherein the second connecting area is larger than the first connecting area. The connector device is disposed between the first connecting portion and the second connecting portion.

In another embodiment of the present invention, the electronic assembly includes a first substrate, a second substrate, and a connector device. The first substrate includes a first connecting portion having a plurality of first connecting points. The second substrate includes a second connecting portion having a plurality of second connecting points, wherein the plurality of second connecting points and the plurality of first connecting points are configured in pairs. The connector device includes a plurality of elastic connectors respectively connected between the pairs of the plurality of first connecting points and the plurality of second connecting points, wherein each of the plurality of elastic connectors forms an inclined angle relative to a normal direction of the first substrate or the second substrate.

In an embodiment, the plurality of first connecting points enclose a first connecting area, and the plurality of second connecting points enclose a second connecting area, wherein the second connecting area is larger than the first connecting area.

In an embodiment, the plurality of first connecting points are arranged in an array, and a distance between a center of one of the plurality of first connecting points and a center of an adjacent one of the plurality of first connecting points defines a first pitch. The plurality of second connecting points are arranged in an array, and a distance between a center of one of the plurality of second connecting points and a center of an adjacent one of the plurality of second connecting points defines a second pitch, wherein the second pitch is larger than the first pitch.

In an embodiment, the area of each of the plurality of second connecting points is larger than the area of each of the plurality of first connecting points.

In an embodiment, the inclined angle increases from a central one of the plurality of elastic connectors to an outer one of the plurality of elastic connectors.

In an embodiment, the inclined angle is greater than or equal to 0° and is less than or equal to 40°.

In an embodiment, each of the plurality of elastic connectors includes a first connector, a second connector, and an elastic component. The first connector is electrically connected to the first connecting portion. The second connector is electrically connected to the second connecting portion. The elastic component is disposed between the first connector and the second connector, and electrically connected to the first connector and the second connector. The plurality of elastic components have different stretched lengths.

In an embodiment, the stretched length increases from a central one of the plurality of elastic components to an outer one of the plurality of elastic components.

In an embodiment, the stretched length of each elastic component is less than or equal to 1.3-fold of an original length of the elastic component.

In an embodiment, the electronic assembly further includes a positioning component, wherein the positioning component is disposed between the first substrate and the second substrate. The positioning component has a plurality of channels, and the plurality of elastic connectors are respectively disposed through the plurality of channels.

In an embodiment, the length of each of the plurality of channels increases from a central one of the plurality of channels to an outer one of the plurality of channels.

In an embodiment, each of the plurality of channels forms an inclined angle relative to the normal direction of the first substrate or the second substrate, and the inclined angle of each of the plurality of channels increases from a central one of the plurality of channels to an outer one of the plurality of channels.

In an embodiment, the inclined angle of each of the plurality of channels is greater than or equal to 0° and is less than or equal to 40°.

In yet another embodiment of the present invention, the electronic assembly includes a first substrate, a connector device, and a positioning component. The first substrate includes a plurality of first connecting points arranged in an array. The connector device includes a plurality of elastic connectors, wherein the plurality of elastic connectors are arranged in an array and respectively electrically connected to the plurality of first connecting points. The positioning component is disposed on a side of the first substrate and has a plurality of channels. The plurality of elastic connectors are respectively disposed through the plurality of channels, and each of the plurality of elastic connectors forms an inclined angle relative to a normal direction of the first substrate.

### BRIEF DESCRIPTION OF THE DRAWINGS

FIG. 1 is a 3D diagram of the electronic assembly in an embodiment of the present invention.

FIG. 2 is a transparent view of some elements of the electronic assembly shown in FIG. 1.

FIG. 3 is a cross-sectional view of the electronic assembly shown in FIG. 1.

FIG. 4 is an enlarged view of a portion of the electronic assembly shown in FIG. 3.

FIG. 5 is a transparent top view of the first substrate and the second substrate in an embodiment of the present invention.

FIG. 6 is an operating diagram of the first substrate and the elastic connector in an embodiment of the present invention.

FIG. 7 is a side view of the connector device in an embodiment of the present invention.

FIG. 8 is a cross-sectional view of the positioning component in an embodiment of the present invention.

FIG. 9 is a schematic diagram of the electronic assembly in another embodiment of the present invention.

FIG. 10 is a schematic diagram of the electronic assembly in another embodiment of the present invention.

### DETAILED DESCRIPTION OF THE INVENTION

The present disclosure will be described in detail below through embodiments and with reference to the accompanying drawings. In the attached figures, for the purpose of clarification, the thicknesses of layers, films, panels, regions and the like are amplified. In the whole specification, the same marks represent the same element. It should be understood that, when an element is described as “being on” or “being connected to” another element, it may be directly on or connected to another element, or there may be other elements therebetween. On the other hand, when an element is described as “directly existing on” or “being directly connected to” another element, there is no element therebetween. As used in the present specification, a “connection” may be a physical and/or electrical connection.

The directional terminology used herein is intended to provide detailed descriptions and is not limiting to the invention. For example, the relative terms “lower”, “upper”, and the like are merely used to describe the relative orientation between one and another element in the figures, depending on the specific viewing angle of the figures. As used herein, the singular forms “a”, “an”, and “the” are intended to include the plural forms, including “at least one”, unless the content dictates otherwise. “Or” means “and/or”. The terms such as “first” and “second” in the present specification are merely used to differentiate an element from another. In the following discussions, “a first element” may be called “a second element” without departing from the teaching of the present disclosure.

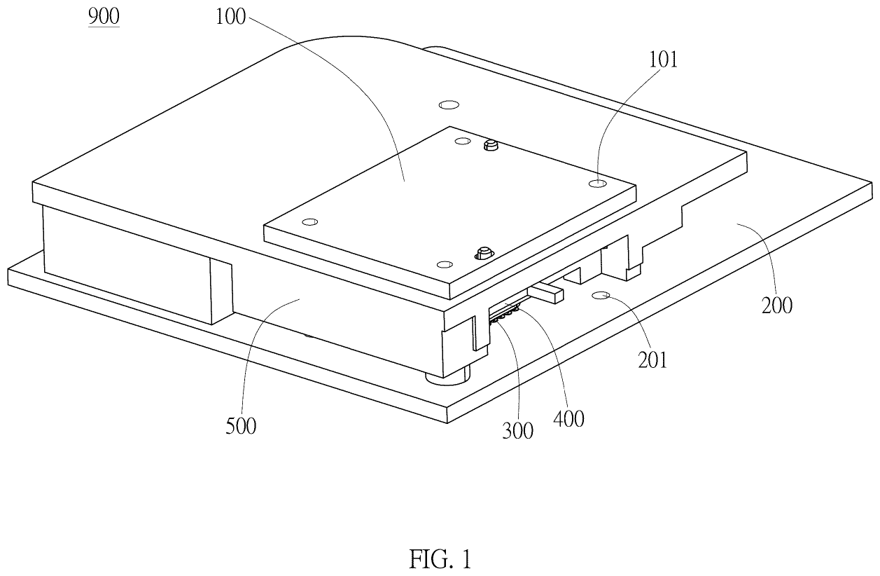

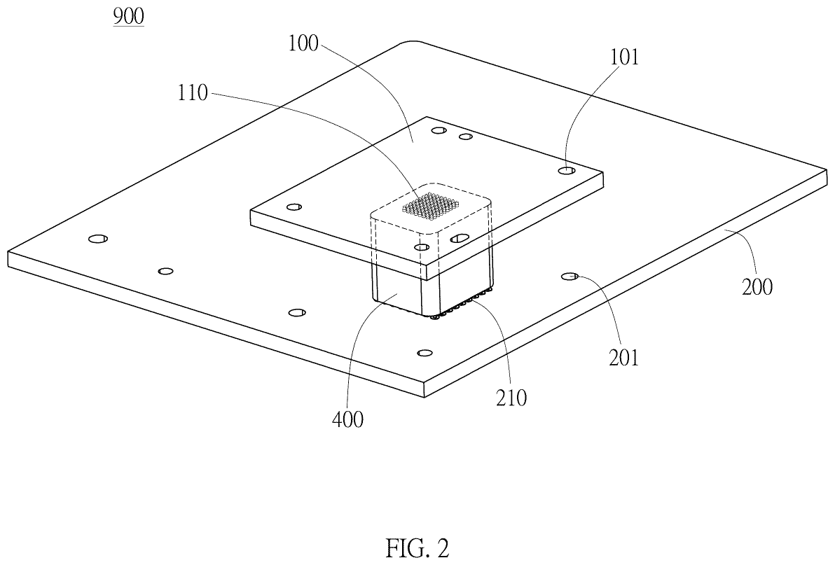

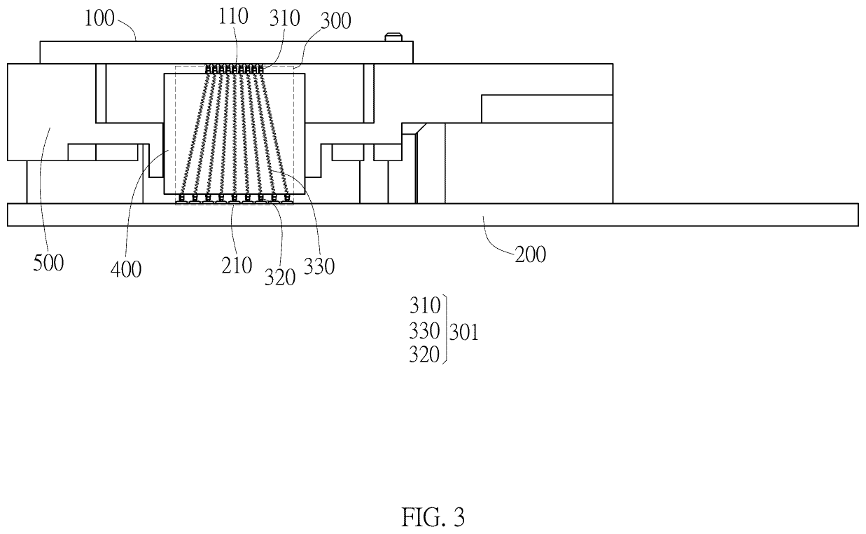

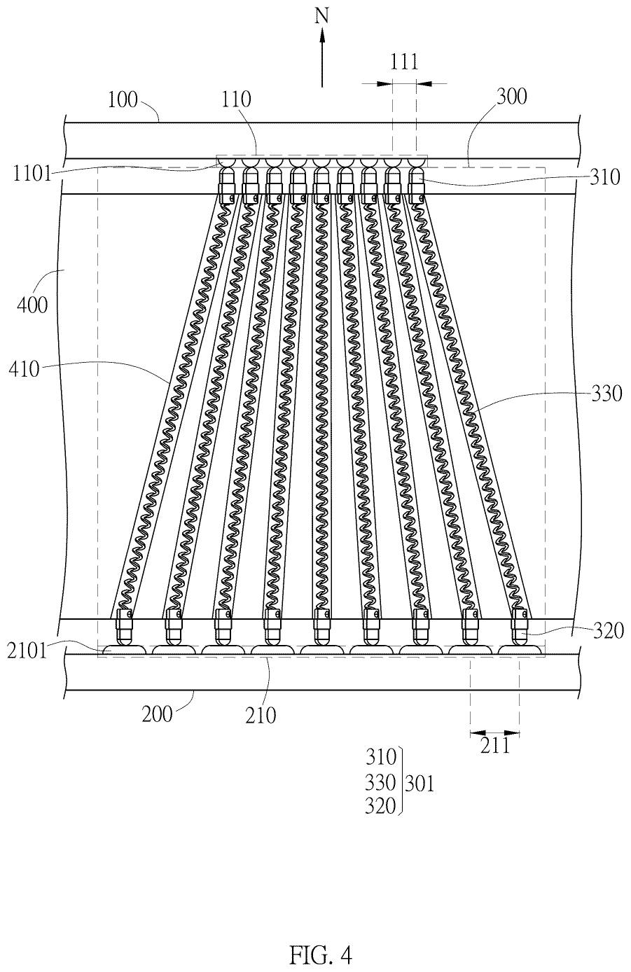

FIG. 1 shows a 3D diagram of the electronic assembly 900 in an embodiment of the present invention. For clear illustration, FIG. 2 retains only some components from FIG. 1, and these components is shown in a partial transparent view. FIG. 3 is a cross-sectional view of the electronic assembly of this embodiment, and FIG. 4 is a partially enlarged view of FIG. 3. As shown in FIGS. 1 to 4, in an embodiment, the electronic assembly 900 may include a first substrate 100, a second substrate 200 and a connector device 300, wherein the electronic assembly 900 may be disposed in an electronic device (not shown in the figures). The first substrate 100 may include a first connecting portion 110, and the first connecting portion 110 has a first connecting area. The second substrate 200 may include a second connecting portion 210, and the second connecting portion 210 has a second connecting area, wherein the second connecting area is larger than the first connecting area. The connector device 300 may be disposed between the first connecting portion 110 and the second connecting portion 210.

Specifically, the first substrate 100 may be a wafer, a chip, a printed circuit board (PCB), or a combination of the like. The second substrate 200 may also be a wafer, a chip, a printed circuit board (PCB), or a combination of the like, wherein the second substrate 200 may be the same or a different form of substrate as the first substrate 100. The first connecting portion 110 on the first substrate 100 may include, but is not limited to, functional connection parts, bonding pads for electrical connection of functional parts, or the combinations thereof. The second connecting portion 210 on the second substrate 200 may also include functional connection parts, bonding pads for electrical connection of functional parts, or the combinations thereof, wherein the second connecting portion 210 may be the same or a different form of connecting portion as the first connecting portion 110. In an embodiment, the first connecting portion 110 and/or the second connecting portion 210 may be functional connection parts, or they can also be bonding pads used to be electrically connected to the connector device 300.

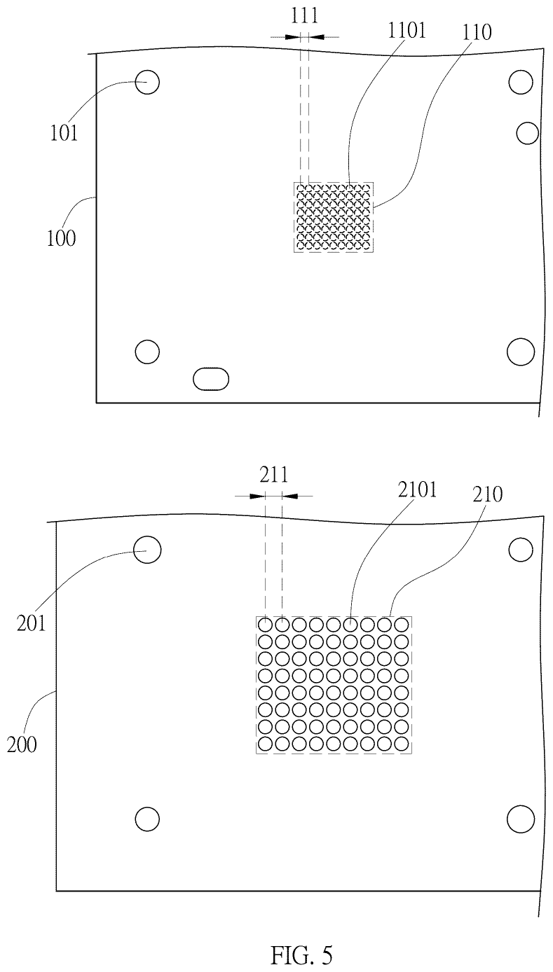

In an embodiment, as shown in FIG. 5, the first connecting portion 110 may include a plurality of first connecting points 1101 arranged in an array such as a linear array, a grid pattern, or the like. The second connecting portion 210 may include a plurality of second connecting points 2101 arranged in an array with a pattern corresponding to the first connecting points 1101 of the first connecting portion 110. The second connecting points 2101 of the second connecting portion 210 and the first connecting points 1101 of the first connecting portion 110 are configured in pairs, for example, in a one-to-one manner. The connector device 300 may be disposed between the first substrate 100 and the second substrate 200, and be electrically connected between the paired first connecting points 1101 and second connecting points 2101.

As shown in FIG. 5, in an embodiment, the first connecting points 1101 may be arranged in an array based on a first pitch 111, wherein the distance between a center of one of the first connecting points 1101 and a center of an adjacent one of the plurality of first connecting points 1101 defines the first pitch 111. The second connecting points 2101 may be arranged in an array based on a second pitch 211, wherein the distance between a center of one of the second connecting points 2101 and a center of an adjacent one of the second connecting points 2101 defines the second pitch 211. The second pitch 211 may be different from the first pitch 111. For example, the second pitch 211 may be larger than the first pitch 111. On the other hand, the first connecting points 1101 may enclose the first connecting area; that is, the outermost first connecting points 1101 define the boundaries of the first connecting area. Similarly, the second connecting points 2101 may enclose the second connecting area; that is, the outermost second connecting points 2101 define the boundaries of the second connecting area. The first connecting points 1101 and the second connecting points 2101 are respectively connected to the two ends of the connector device 300. When the second pitch 211 is larger than the first pitch 111, the second connecting area is larger than the first connecting area.

In addition, in order to maintain electrical contact between the second connecting points 2101 and the connector device 300, the area of each second connecting point 2101 is preferably larger than the area of each first connecting points 1101. Based on this configuration, even if the first connecting portion 110 and the second connecting portion 210 are slightly misaligned in the assembling process, for example, a displacement may occur, or there may be discrepancies in the pitches between the connecting points, the electrical connection to the connector device 300 can still be maintained because of the relative larger second connecting area and/or the relative larger area of the second connecting point 2101.

In an embodiment, as shown in FIG. 4, the connector device 300 may include a plurality of elastic connectors 301, wherein the two ends of each elastic connector 301 are used to be respectively connected to a corresponding paired first connecting points 1101 and second connecting points 2101. The elastic connectors 301 may be radially positioned from the first substrate 100 to the second substrate 200. For example, the elastic connectors 301 may be arranged more compactly at the ends close to the first substrate 100, and more loosely at the other ends close to the second substrate 200. Based on this configuration, the pitch of the connecting points in a connecting portion can be enlarged for convenient connection to another connecting portion with connecting points of different pitches, allowing for larger assembly tolerances.

As shown in FIG. 4, in an embodiment, each elastic connector 301 in the electronic assembly may include a first connector 310, a second connector 320, and an elastic component 330. The first connector 310 may contact and be electrically connected to the first connecting portion 110 (for example, to the first connecting point 1101). The second connector 320 may contact and be electrically connected to the second connecting portion 210 (for example, to the second connecting point 2101). The elastic component 330 may be disposed between the first connector 310 and the second connector 320 and electrically connected to the first connector 310 and the second connector 320. The elastic connectors 301 may be arranged in an array corresponding to the first connecting points 1101 or the second connecting points 2101, wherein first substrate 100 and the second substrate 200 (more specifically, the planes in which the first connecting portion 110 and the second connecting portion 210 lie) preferably have the same normal direction N, but not limited thereto. The elastic connectors 301 in the connector device 300 may be arranged to match the patterns of the first connecting points 1101 of the first connecting portion 110 and the second connecting points 2101 of the second connecting portion 210 (referring to FIG. 5). In addition, because the second pitch 211 is different from the first pitch 111, the elastic components 330 may have different stretched lengths, wherein the stretched length refers to the linear distance between the two ends of each elastic component 330.

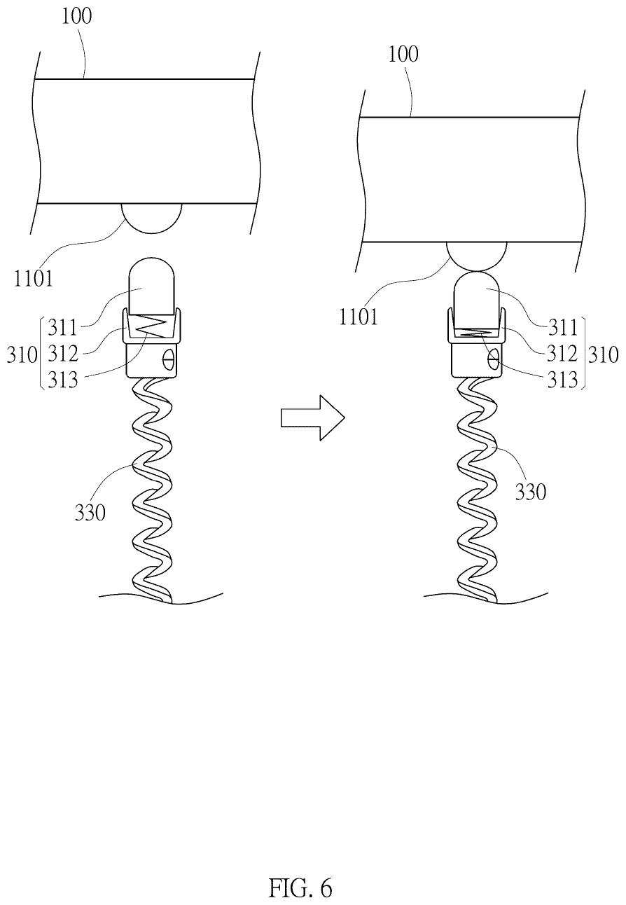

Specifically, in each elastic connector 301, the first connector 310 and/or the second connector 320 may include bonding pads, probes, pogo pin connectors, and the like. Preferably, at least one of the first connector 310 and the second connector 320 is a pogo pin connector. More preferably, both the first connector 310 and the second connector 320 are pogo pin connectors. As shown in FIG. 6, in an embodiment, the first connector 310 may be a pogo pin connector which includes a head 311, a spring 312 and a housing 313. The spring 312 is disposed within the housing 313 and connected to the head 311, and the housing 313 is electrically connected to the elastic component 330. When the second connector 320 is also a pogo pin connector, the second connector 320 (not shown in FIG. 6) may have a similar design to the first connector 310. For example, when the first connector 310 is not in contact with a connecting portion (such as the first connecting portion 110), the spring 312 may remain its original length, and the head 311 may have little or no contact with the housing 313. After the first connector 310 contacts the first connecting portion 110 (such as the first connecting point 1101), the spring 312 can be compressed, increasing the contact area between the head 311 and the housing 313. The head 311 and the housing 313 may include conductive materials to form a conducting path through the first connecting portion 110, the first connector 310, and the elastic component 330. Based on this configuration, the substrate in the electronic assembly can be quickly assembled and disassembled to facilitate the testing and assembly of the connecting portion.

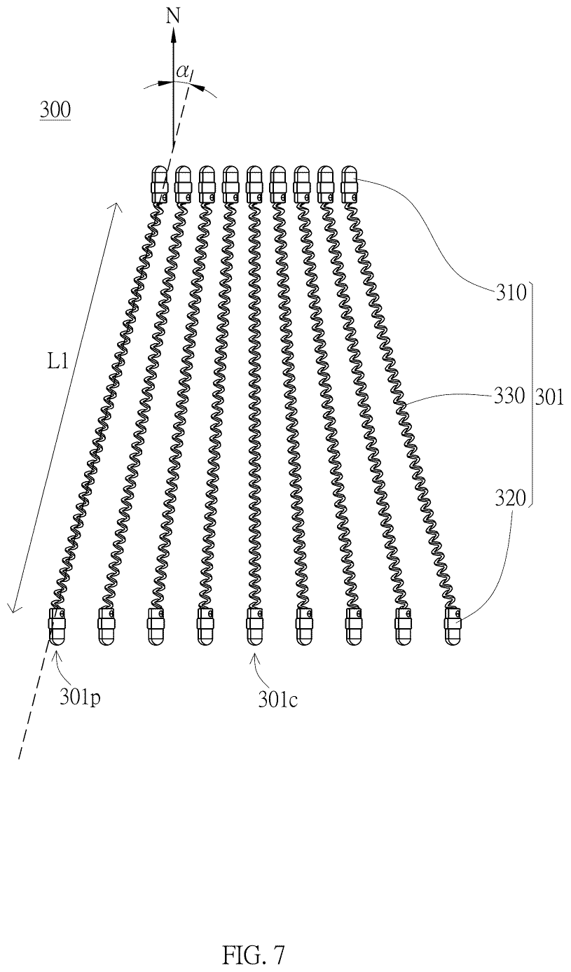

As shown in FIG. 7, in an embodiment, the stretched length L1 of the elastic component 330 may increase from a central one of the elastic components 330 to an outer one of the elastic components 330. That is, the stretched length L1 of the elastic component 330 positioned more centrally may be lesser, or the stretched length L1 of the elastic component 330 positioned more outwardly may be greater. For example, in a cross-sectional plane of the electronic assembly (as shown in FIG. 7), for the configuration that an odd number of elastic connectors 301 are arranged along a direction, the elastic component 330 in the elastic connector 301c, which is centrally positioned, may have the minimum stretched length L1; for example, the stretched length L1 may be its original length (not stretched). For another configuration (not shown in the figures), wherein an even number of elastic connectors 301 are arranged along a direction, the elastic components 330 in the two elastic connectors 301, which are positioned close to the center, may both have the minimum stretched length L1. Meanwhile, the stretched length L1 of the elastic component 330 in other elastic connectors 301 may be greater than its original length, and the stretched length L1 may gradually increase from the center to the outer sides. For example, the elastic component 330 of the elastic connector 301p, which is positioned outermost, may have the greatest stretched length L1. That is, the stretched length L1 increases as the distance from the center of the array to the corresponding elastic component 330 increases.

Preferably, each elastic component 330 has the electrically conductive property; for example, the elastic component 330 can be springs or elastomers formed with metal, conductive plastics, or the like. Generally, in order to prevent elastic fatigue of the elastic component 330, the stretched length L1 (as shown in FIG. 7) of each elastic component 330 may be designed to be less than or equal to 1.3-fold of the original length of the elastic component 330. For example, the greatest stretched length L1 in all elastic components 330 (that is, the stretched length L1 of the outermost elastic component 330) is preferably 1.2-fold to 1.3-fold of its original length, but not limited thereto. According to the different material properties of the elastic components 330 in various designs, the greatest stretched length L1 in all elastic components 330 can be set with different upper limit values, for example, being greater than 1.3-fold of its original length and still less than the stretched length at which elastic fatigue occurs. Based on this configuration, although the linear distance between the two ends of each elastic connector 301 differs, the current path through each elastic component 330, which is bent or curled (such as coiled in a spiral shape), still have the same length, ensuring same signal transmission speed and quality between every pair of the first connecting point 1101 and the second connecting point 2101.

From another aspect, as shown in FIG. 7, each elastic connector 301 may form an inclined angle α relative to the normal direction N of the first substrate 100 or the second substrate 200 (or the stacking direction of the first substrate 100 and the second substrate 200). The inclined angle α of the elastic connector 301 may increase from a central one of the elastic connectors (such as 301c) to an outer one of the elastic connectors (such as 301p). In other words, in the connector device 300, the inclined angle α of the elastic connector 301 positioned more centrally may be lesser, or the inclined angle α of the elastic connector 301 positioned more outwardly may be greater. Specifically, the inclined angle α here refers to the inclined angle of each elastic component 330 relative to the normal direction N of the first substrate 100 or the second substrate 200, that is, the angle between a line connecting the two ends of each elastic component 330 and the normal direction N (or stacking direction). In an embodiment, the elastic connector 301c, which is centrally positioned, may have the minimum inclined angle α, or the extension direction of the elastic connector 301c may be the same as the normal direction N (that is, the inclined angle α is 0°). Meanwhile, The inclined angles α of other elastic connectors 301 may gradually increase from the center to the outer sides. For example, the inclined angle α of the elastic connector 301p, which is positioned outermost, may be the greatest. That is, preferably, the inclined angle α increases as the distance from the center of the array to the corresponding elastic connector 301 (or the elastic component 330) increases. The above design of the inclined angle α of the elastic connectors 301 may also relate to the stretched length L1 of the elastic components 330. As the inclined angle α of the elastic connector 301 increases, the stretched length L1 of the corresponding elastic component 330 increases. In some embodiments, in order to keep the stretched length L1 of each elastic component 330 in the elastic range, the inclined angle α may be provided with an upper limit value. For example, for the configuration that the first substrate 100 and the second substrate 200 is stacked along the normal direction N, preferably, the inclined angle α is greater than or equal to 0°and is less than or equal to 40°, keeping the stretched length L1 of each elastic component 330 being less than or equal to 1.3-fold of its original length. In other words, the greatest inclined angle α (that is, the inclined angle α of the outermost elastic connector 301 p) is preferably less than or equal to 40°, more preferably, between 34° and 40°, but not limited thereto. According to the different material properties of the elastic component 330 in various designs, the greatest inclined angle in all elastic connectors 301 can be set with different upper limit values, for example, being greater than 40°. Considering that the elastic connectors 301 can be arranged in three-dimensional space, the discussions above regarding angles and directions are applicable beyond the content shown in FIG. 7 and can also be extended to three-dimensional configurations.

As shown in FIG. 4, in some embodiments of the present invention, the electronic assembly may further include a positioning component 400 disposed between the first substrate 100 and the second substrate 200. The positioning component 400 may have a plurality of channels 410, and the elastic connectors 301 are respectively disposed through the channels 410. Specifically, the positioning component 400 may include an insulating housing or board to separate the adjacent elastic connectors 301, preventing contacts and the resulting short circuit between the elastic connectors 301. The first connector 310 and the second connector 320 of each elastic connector 301 may be respectively disposed on the opposite sides of the positioning component 400 and extend out of the corresponding channel 410. In addition, the length and/or inclined angle of the channels 410 may be aligned with the stretched and/or inclined configuration of the elastic components 330, simplifying the positioning process of the elastic connectors 301. In an embodiment, each elastic component 330 may preferably be adjusted to the predetermined stretched length corresponding to the predetermined position (for example, the elastic component 330 for the outermost position is stretched to 1.3-fold of the original length, while the elastic component 330 for the center position remains unstretched) prior to being assembled with the positioning component 400; then, the elastic components 330 with the predetermined stretched length can be positioned into the corresponding channels 410 of the positioning component 400. The two ends of each elastic component 330 may be connected to the first connector 310 and the second connector 320 using methods such as interlocking, welding, and the like.

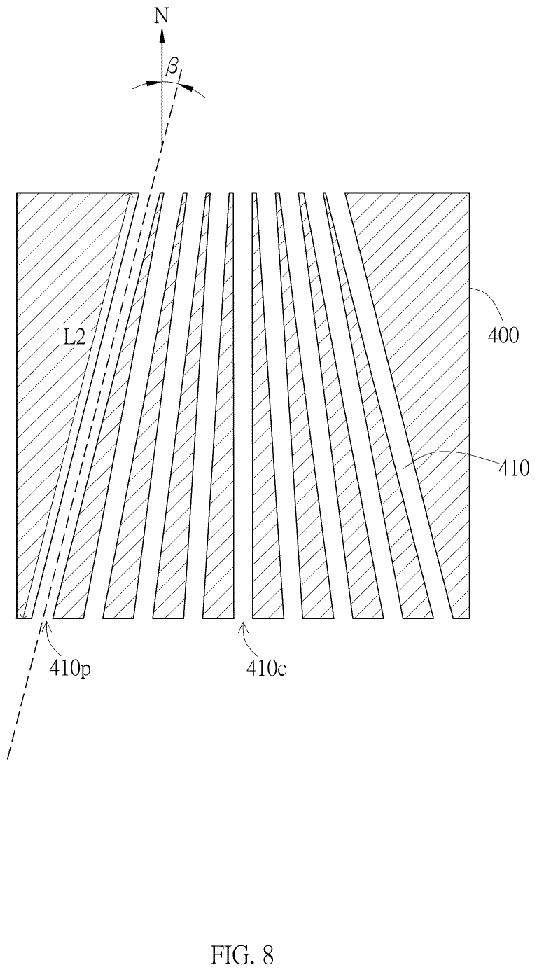

As shown in FIG. 8, corresponding to the abovementioned configuration of the elastic connectors 301, the channels 410 in the positioning component 400 may have different length L2. In an embodiment, the length L2 of the channel 410 increases from a central one of the channels (such as 410c) to an outer one of the channels (such as 410p). That is, the length L2 of the channel 410 positioned more centrally may be lesser, or the length L2 of the channel 410 positioned more outwardly may be greater. For example, the channel 410c, which is centrally positioned, may have the minimum length L2; the channel 410p, which is positioned outermost, may have the greatest length L2. In another aspect, each channel 410 may form an inclined angle β relative to the normal direction N of the first substrate 100 or the second substrate 200 (or the stacking direction thereof). The inclined angle β of the channel 410 may increase from a central one of the channels (such as 410c) to an outer one of the channels (such as 410p). That is, the inclined angle β of the channel 410 positioned more centrally may be lesser, or the inclined angle β of the channel 410 positioned more outwardly may be greater. For example, the channel 410c, which is centrally positioned, may have the minimum inclined angle β, or the extension direction of the channel 410c may be the same as the normal direction N (that is, the inclined angle β is 0°); the channel 410 p, which is positioned outermost, may have the greatest inclined angle β. The inclined angle β of the channel 410 may be close to or equal to the inclined angle α of the corresponding elastic connector 301. In some embodiments, in order to keep the stretched length L1 (referring to FIG. 7) of each elastic component 330 positioned in the corresponding channel 410 being less than or equal to 1.3-fold of its original length, the inclined angle β of each channel 410 may be limited to be greater than or equal to 0° and be less than or equal to 40°. In another aspect, the inclined angle β and the length L2 of the channel 410 are preferably aligned with (or is equal to) the inclined angle α and the stretched length L1 of the elastic component 330.

Furthermore, in some embodiments, the electronic assembly 900 may include a frame 500 (referring to FIGS. 1 and 3), wherein the frame 500 may be disposed between the first substrate 100 and the second substrate 200 to support or secure the first substrate 100, the second substrate 200 and/or the positioning component 400. The first substrate 100 and the second substrate 200 may include assembly holes, protrusions, grooves, and other structures facilitating alignment during assembly, for example, the first assembly holes 101 on the first substrate 100 and the second assembly holes 201 on the second substrate 200 (referring to FIG. 5). The first assembly holes 101 may be aligned with the second assembly holes 201. The frame 500 may be designed with bumps or grooves matching the assembly holes or other structures of the first substrate 100 and the second substrate 200. In addition, the frame 500 may form a cavity together with the first substrate 100 and the second substrate 200 to accommodate and secure the positioning component 400 (referring to FIG. 3). In other embodiments, the positioning component 400 itself may also feature structures for alignment to facilitate its positioning with respect to the first substrate 100 and the second substrate 200. In addition, the first assembly holes 101 on the first substrate 100 and the second assembly holes 201 on the second substrate 200 may be used to secure the electronic assembly 900 within the electronic device.

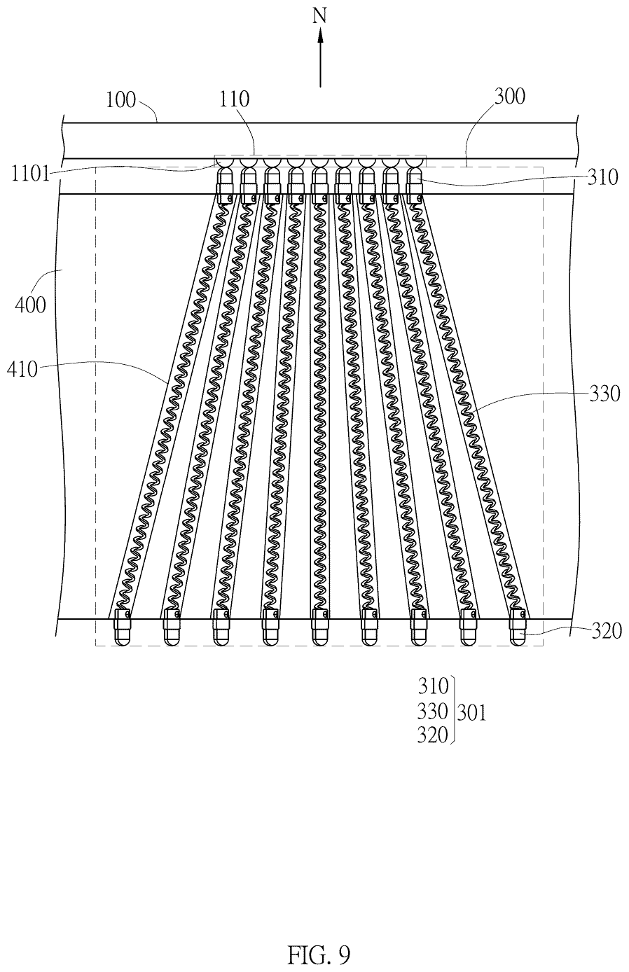

As shown in FIG. 9, in an embodiment, the electronic assembly 900 may include a first substrate 100, a connector device 300 and a positioning component 400. The first substrate 100 may include a first connecting portion 110, and the first connecting portion 110 includes a plurality of first connecting points 1101 arranged in an array. The connector device 300 may include a plurality of elastic connectors 301 arranged in an array, and the elastic connectors 301 are respectively electrically connected to the first connecting points 1101. The positioning component 400 may be disposed on a side of the first substrate 100. The positioning component 400 may have a plurality of channels 410, and the elastic connectors 301 may be respectively disposed through the channels 410. Each elastic connector 301 may form an inclined angle relative to a normal direction N of the first substrate 100. In other words, the elastic connectors 301 may radially extend outwardly from the first substrate 100. Based on this configuration, the pitch of the connecting points in a connecting portion can be enlarged, facilitating the subsequent assembling or testing process and allowing for larger assembly tolerances.

The present embodiment can be combined with the various designs from the aforementioned embodiments. For example, each elastic connector 301 may include the first connector 310, the second connector 320, and the elastic component 330. The first connector 310 may be electrically connected to the first connecting portion 110, and the elastic component 330 may be disposed between and electrically connected to the first connector 310 and the second connector 320. Corresponding to the radial arrangement of the elastic connectors 301, the plurality of elastic components 330 may have different stretched lengths L1 (referring to FIG. 7). Based on different designs and applications, the stretched length L1 of each elastic component 330 may be set with an upper limit value, for example, less than or equal to 1.3-fold of the original length of the elastic component 330, keeping within the elastic range. In addition, each elastic connector 301 may form an inclined angle α relative to the normal direction N of the first substrate 100 (referring to FIG. 7). Corresponding to different stretched lengths L1 of the elastic components 330, the inclined angle α of the elastic connector 301 may increase from a central one of the elastic connectors 301 to an outer one. That is, in the connector device 300, the inclined angle α of the elastic connector 301 positioned more centrally may be lesser, or the inclined angle α of the elastic connector 301 positioned more outwardly may be greater. In alignment with the design of the stretched length L1 of each elastic component 330, the inclined angle α of each elastic connector 301 may be set with an upper limit value, for example, less than or equal to 40°. Moreover, the channels 410 in the positioning component 400 may have different lengths L2 (referring to FIG. 8), wherein the length L2 increases from a central one of the channels 410 to an outer one. That is, the length L2 of the channel 410 positioned more centrally may be lesser, or the length L2 of the channel 410 positioned more outwardly may be greater. Similarly, each channel 410 may form an inclined angle β relative to the normal direction N of the first substrate 100 (referring to FIG. 8), wherein the inclined angle β of each channel 410 may increase from a central one of the channels 410 to an outer one. That is, the inclined angle β of the channel positioned more centrally (such as 410c) may be lesser, or the inclined angle β of the channel positioned more outwardly (such as 410p) may be greater. In alignment with the design of the stretched length of each elastic connector 301, the inclined angle β of each channel 410 may be set with an upper limit value, for example, less than or equal to 40°.

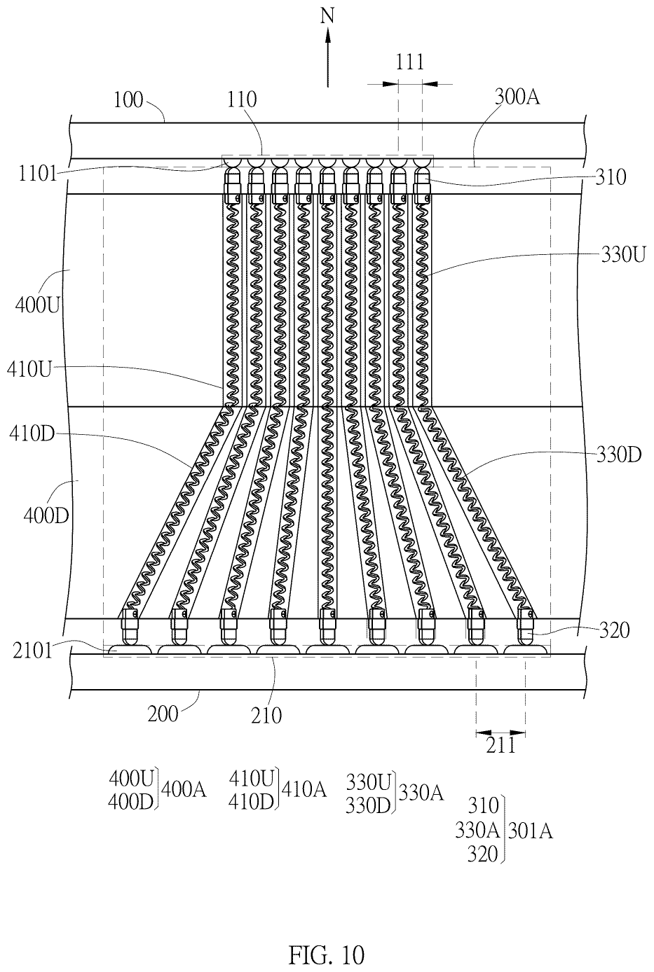

Moreover, in the electronic assembly of the invention, the shape or size of the components is not limited to the figures. For example, the elastic connector may not be disposed linearly and can have a bent configuration according to different processes or purposes. As shown in FIG. 10, in another embodiment, the connector device 300A includes a plurality of elastic connectors 301A, wherein the extending direction of each elastic connector 301A from the end close to the first substrate 100 may be the same as the normal direction N of the first substrate 100, while the extending direction of each elastic connector 301A from the other end (close to the second substrate 200) may form an inclined angle relative to the normal direction N of the second substrate 200. Specifically, the elastic component 330A of each elastic connector 301A may include a vertical segment 330U and an inclined segment 330D connected to each other, wherein the vertical segment 330U is connected to the first connector 310, and the inclined segment 330D is connected to the second connector 320. The vertical segment 330U of the elastic component 330A in each elastic connectors 301A may be disposed parallel to each other, and the inclined angle of the vertical segment 330U relative to the normal direction N of the first substrate 100 is substantially 0° (that is, the vertical segment 330U is positioned parallel to the normal direction N). The inclined segment 330D of the elastic component 330A in each elastic connectors 301A may be arranged similar to the inclined or stretched configuration of the elastic component 330 shown in FIG. 7, so that the inclined angle or the stretched length of the inclined segment 330D is configured to increase from a central one of the elastic connector to an outer one. In this embodiment, the inclined angle of each elastic connector 301A substantially refers to the angle between the direction of the line connecting both ends of each inclined segment 330D and the normal direction N (or the stacking direction of the first substrate 100 and the positioning component 400). The details regarding the inclined or stretched configuration of the inclined segments 330D can be referred to aforementioned embodiments (for example, as shown in FIG. 7), and no further elaboration will be provided here.

In an embodiment, corresponding to the bent configuration of the elastic component 330A, each channel 410A in the positioning component 400A may be an integral channel with one bend, but not limited thereto. As shown in FIG. 10, corresponding to the vertical segment 330U and the inclined segment 330D of the elastic component 330A, the positioning component 400A may include a first sub-positioning component 400U and a second sub-positioning component 400D, which are separable from each other. The first sub-positioning component 400U may have a plurality of first sub-channels 410U; the second sub-positioning component 400D may have a plurality of second sub-channels 410D, wherein the first sub-channels 410U are respectively communicated with the corresponding second sub-channels 410D to form a plurality of channels 410A. Corresponding to the vertical segments 330U of the elastic components 330A, the first sub-channels 410U of the first sub-positioning component 400U may be positioned parallel to the normal direction N, respectively accommodating the vertical segments 330U. Corresponding to the inclined segments 330D of the elastic components 330A, the second sub-channels 410D of the second sub-positioning component 400D respectively accommodate the inclined segments 330D of the elastic components 330A. The second sub-channels 410D may be arranged similar to the inclined configuration or length design of the channels 410 shown in FIG. 8, so that the inclined angle or the length of the second sub-channel 410D is configured to increase from a central one of the second sub-channel to an outer one. The details regarding the inclined configuration or length design of the second sub-channels 410D can be referred to aforementioned embodiments (for example, as shown in FIG. 8), and no further elaboration will be provided here. Based on this configuration, the spatial arrangement of the components within the electronic assembly and the layout of the electronic assembly in the electronic device can be flexibly adjusted, but not limited thereto.

Through the aforementioned embodiments, the electronic assembly in the present invention utilizes the radially positioned elastic connectors to enlarge the pitch of the connecting points in a connecting portion, facilitating the subsequent assembling or testing process and allowing for larger assembly tolerances. For example, the electronic assembly in the present invention can be applied to the assembling or testing of circuits with electronic components that need to be precisely arranged, for example, the System On Wafer (SOW). By using the elastic connector designed to match multiple pitches, the assembly tolerance can be absorbed, avoiding complex multi-layer positioning process and improving efficiency and quality yield of the assembling process.

The present invention has been illustrated by the above embodiments. However, the above embodiments are only exemplary and are not to be regarded as limiting. Based on different designs, some components in one embodiment may be applied to another embodiment, but not limited thereto. The scope of the present invention is defined by the appended patent claims. Various changes and modifications to the present invention can be made by a person having ordinary skill in the art without departing from the spirit of the present invention, and that various changes and modifications fall within the scope of the present invention as defined by the appended patent claims.

What is claimed is:

1. An electronic assembly, comprising:
a first substrate comprising a first connecting portion, the first connecting portion having a first connecting area;
a second substrate comprising a second connecting portion, the second connecting portion having a second connecting area, wherein the second connecting area is larger than the first connecting area; and
a connector device disposed between the first connecting portion and the second connecting portion.

2. An electronic assembly, comprising:
a first substrate comprising a first connecting portion having a plurality of first connecting points;
a second substrate comprising a second connecting portion having a plurality of second connecting points, wherein the plurality of second connecting points and the plurality of first connecting points are configured in pairs; and
a connector device comprising a plurality of elastic connectors respectively connected between the pairs of the plurality of first connecting points and the plurality of second connecting points, wherein each of the plurality of elastic connectors forms an inclined angle relative to a normal direction of the first substrate or the second substrate.

3. The electronic assembly of claim 2, wherein the plurality of first connecting points enclose a first connecting area, the plurality of second connecting points enclose a second connecting area, and the second connecting area is larger than the first connecting area.

4. The electronic assembly of claim 2, wherein the plurality of first connecting points are arranged in an array; a distance between a center of one of the plurality of first connecting points and a center of an adjacent one of the plurality of first connecting points defines a first pitch; the plurality of second connecting points are arranged in an array; a distance between a center of one of the plurality of second connecting points and a center of an adjacent one of the plurality of second connecting points defines a second pitch; the second pitch is larger than the first pitch.

5. The electronic assembly of claim 2, wherein an area of each of the plurality of second connecting points is larger than an area of each of the plurality of first connecting points.

6. The electronic assembly of claim 2, wherein the inclined angle increases from a central one of the plurality of elastic connectors to an outer one of the plurality of elastic connectors.

7. The electronic assembly of claim 6, wherein the inclined angle is greater than or equal to 0° and is less than or equal to 40°.

8. The electronic assembly of claim 2, wherein each of the plurality of elastic connectors comprises:
a first connector electrically connected to the first connecting portion;
a second connector electrically connected to the second connecting portion; and
an elastic component disposed between the first connector and the second connector and electrically connected to the first connector and the second connector,
wherein the plurality of elastic components have different stretched lengths.

9. The electronic assembly of claim 8, wherein the stretched length increases from a central one of the plurality of elastic components to an outer one of the plurality of elastic components.

10. The electronic assembly of claim 8, wherein the stretched length of each elastic component is less than or equal to 1.3-fold of an original length of the elastic component.

11. The electronic assembly of claim 2, further comprising a positioning component disposed between the first substrate and the second substrate, wherein the positioning component has a plurality of channels, and the plurality of elastic connectors are respectively disposed through the plurality of channels.

12. The electronic assembly of claim 11, wherein each of the plurality of channels has a length and the length increases from a central one of the plurality of channels to an outer one of the plurality of channels.

13. The electronic assembly of claim 11, wherein each of the plurality of channels forms an inclined angle relative to the normal direction of the first substrate or the second substrate, and the inclined angle increases from a central one of the plurality of channels to an outer one of the plurality of channels.

14. The electronic assembly of claim 13, wherein the inclined angle of each of the plurality of channels is greater than or equal to 0° and is less than or equal to 40°.

15. An electronic assembly, comprising:
a first substrate comprising a plurality of first connecting points arranged in an array;
a connector device comprising a plurality of elastic connectors arranged in an array and respectively electrically connected to the plurality of first connecting points; and
a positioning component disposed on a side of the first substrate, the positioning component having a plurality of channels, wherein the plurality of elastic connectors are respectively disposed through the plurality of channels, and each of the plurality of elastic connectors forms an inclined angle relative to a normal direction of the first substrate.

16. The electronic assembly of claim 15, wherein the inclined angle increases from a central one of the plurality of elastic connectors to an outer one of the plurality of elastic connectors.

17. The electronic assembly of claim 16, wherein the inclined angle is greater than or equal to 0° and is less than or equal to 40°.

18. The electronic assembly of claim 15, wherein each of the plurality of channels has a length and the length increases from a central one of the plurality of channels to an outer one of the plurality of channels.

19. The electronic assembly of claim 15, wherein each of the plurality of elastic connectors comprises an elastic component, an end of the elastic component is electrically connected to the first connector; the plurality of elastic components are respectively disposed within the plurality of channels and have different stretched lengths; the stretched length increases from a central one of the plurality of elastic components to an outer one of the plurality of elastic components.

20. The electronic assembly of claim 19, wherein the stretched length of each elastic component is less than or equal to 1.3-fold of an original length of the elastic component.
